(19) United States
(12) Patent Application Publication
(10) Pub. No.: US 2004/0214448 A1
(43) Pub. Date: Oct. 28, 2004

(54) Method of ashing a photoresist

(75) Inventors: Bor-Wen Chan, Hsinchu (TW); Yuan-Hung Chiu, Taipei (TW); Han-Jan Tao, Hsinchu (TW)

Correspondence Address: GEORGE 0. SAILE, 28 DAVIS AVENUE, POUGHKEEPSIE, NY, 12603, US

(73) Assignee: Taiwan Semiconductor Manufacturing Co.

(21) Appl. No.: 10/420,591

(22) Filed: Apr. 22, 2003

(51) Int. Cl. H01L 21/302; H01L 21/461

(52) U.S. Cl. 438/725

(57) ABSTRACT

A method is provided for stripping a photoresist with a carbonized crust formed during a high dose ion implant. The method may be performed in any etch tool or asher including those where a plasma is generated with a RF discharge source and bias power and tools with a microwave downstream plasma flow. An ICP plasma source is preferred for generating plasma from a flow of oxygen and one or more CₓH_{y}F_{z} gases such as CH₃F and CH₂F₂ where x, y and z are ≧1. A high photoresist removal rate of from 0.2 to 2 microns per minute is achieved while reducing thickness loss in exposed oxide, polysilicon, and silicon layers compared with conventional methods that employ O₂ and C_{M}F_{N} gases. For NMOS and PMOS transistors, Idsat and contact junction leakage are improved.

### FIELD OF THE INVENTION

The invention relates to a method of fabricating an integrated circuit in a semiconductor device. More particularly, the present invention is directed to removing an ion implanted photoresist layer without damaging the substrate during a microelectronics fabrication.

### BACKGROUND OF THE INVENTION

During the fabrication of transistors, resistors, diodes, and other microelectronic devices, a common practice is the implantation of a dopant into a substrate. In a transistor, the implant is directed to a portion of an active area between isolation regions. The dopant is typically B, P, or As ions that are implanted at high energy of up to 150 keV to form features such as lightly doped source/drain (S/D) regions or more heavily doped S/D regions in the substrate. Other parts of a device including a gate electrode and sidewall spacers adjacent to the gate may also be doped by an ion implant process.

The ion implant is performed through a mask that is usually a photoresist layer which is patterned to selectively expose regions of the substrate that are to be doped. The photoresist must be thick enough to prevent ions from reaching protected substrate regions. Unfortunately, the mask is not inert toward the high energy ions. As a result, the top portion of the photoresist layer is transformed into a carbonized crust that is difficult to remove because of its low solubility in wet strippers. A plasma etch can successfully strip the crust but often the etchant attacks the substrate or other portions of a device to cause a loss in performance.

For example, a substrate 7 is shown in FIG. 1a which has shallow trench isolation (STI) features 8 that define an active area 9 on substrate 7. A gate dielectric layer 10, gate layer 11, and sidewall spacers 12 are formed by conventional methods. A photoresist layer 13 is patterned to cover active area 9 and to expose adjacent active areas (not shown). An ion implant 14 with p-type or n-type ions delivers a high dose of ions into a top portion of photoresist 11 and into exposed regions (not shown) of substrate 7 and STI features 8 adjacent to active area 9.

Referring to FIG. 1b, a carbonized crust 16 and a highly doped photoresist layer 15 are formed above undoped photoresist layer 13. Generally, a plasma ashing method 17 that includes oxygen and a fluorocarbon such as CF₄ or C₂F₆ is performed to strip the crust 16 and photoresist layers 13, 15. FIG. 1c shows that the plasma etchant has attacked gate layer 11 to produce a gate layer 11a that has a smaller thickness than gate layer 11 indicated by the distance d₁ from the original surface of layer 11 to the top of gate layer 11a. This thickness loss d₁ is likely to result in a degradation of saturation current (Idsat) in the device. Furthermore, the plasma etchant has also removed a portion of substrate 7 to leave a divot 19 with a height d₂ between STI feature 8 and gate electrode 10. The divot 19 is also detrimental to device performance. Additionally, an undercut 18 is formed by removal of a portion of gate dielectric layer 10 which can lead to a contact junction leakage in the final device.

The plasma etch tool may vary from a barrel type where a plasma is generated in the same chamber as the substrate to a downstream type in which the plasma is generated in a one chamber and is directed towards the substrate in a second chamber through a tube or an inlet. Inductively coupled plasma (ICP) sources and transformer coupled plasma (TCP) sources have become popular since the plasma density and the ion energy are independently controlled to enable an efficient removal of a layer while minimizing the amount of high energy ions that strike the substrate. High energy ions can etch the substrate and force trace metal contaminants from the photoresist into the substrate. To satisfy the throughput requirements for a manufacturing line, a photoresist removal rate of about 0.5 to 1 micron per minute is preferred. Achieving the delicate balance between high removal rates and minimizing substrate damage requires fine tuning the process chemistry, especially for gate lengths of less than 100 nm since shrinking ground rules require finer tolerances in device performance.

Oxygen plasma is frequently as an etchant to remove a photoresist film that serves as an etch mask since the oxygen radicals react with C, H, S, and N in the polymer and photosensitive material components to afford their respective oxides which are volatile. However, pure O₂ plasma is not able to strip the crust on a high dose implanted photoresist layer. Methods have been developed as described in U.S. Pat. No. 6,024,887 that combine C₂F₆ with O₂ in a first plasma etch step and then follow with an O₂ only ashing step to remove a photoresist crust. Similarly, in U.S. Pat. No. 6,352,936, water is employed as an oxygen and hydrogen source and combined with CF₄ in a first plasma ash step and O₂ plasma is then used in a second step to complete the strip process.

Another prior art method in U.S. Pat. No. 6,082,374 mentions a photoresist strip method involving a sapphire plasma tube and a gas chemistry consisting of a fluorocarbon, oxygen, and forming gas. An example of a CF₄/O₂ only method is included but a high oxide loss is shown for temperatures near 200° C. while at temperatures approaching 100° C., the removal rate is too low to be useful in a high throughput manufacturing line.

A low temperature strip method with a high photoresist removal rate is cited in U.S. Pat. No. 5,824,604 and involves an oxidizing gas, a halide containing gas, and a hydrocarbon. Although addition of the hydrocarbon slows down removal rate somewhat, a 1 micron thick arsenic implanted photoresist layer is stripped in 3 minutes while minimizing oxide loss to 9 Angstroms.

Temperature is usually an important variable in a photoresist strip method. The plasma etch strip of a photoresist layer is often facilitated by heating the substrate at temperatures of up to about 250° C. However, care must be taken since pockets of gas within the photoresist may explode or pop at high temperatures. The ejected material may stick to the reactor walls and cause a contamination problem. A low temperature process is claimed in U.S. Pat. No. 6,231,775 which involves SO₃ by itself or combined with oxygen or other etching gases. However, the proper handling of SO₃ requires temperature control that includes a special manifold system

A low temperature photoresist strip process involving O₂ and a fluorocarbon plasma etch is described in U.S. Pat. No. 6,207,583 but is concerned primarily with minimizing damage to sidewalls in underlying dielectric layers and does not address the issue of removing a high dose ion implanted photoresist layer. In related art in U.S. Pat. No. 6,379,576, the capacitive coupling between a substrate and a plasma generated from a mixture of fluorocarbon, O₂, and hydrogen gases is increased to promote the rate of stripping a high dose implanted photoresist. However, the method does not teach the importance of avoiding fluorocarbons like CF₄ to minimize substrate damage.

Therefore, an improved method of removing a high dose implant photoresist layer that avoids the use of C_{M}F_{N} gases in order to minimize damage to substrates including polysilicon and oxide dielectric layers while enabling an efficient removal rate is needed. The method should be applicable to a reactor that has a radio frequency (RF) discharge in source and power and to a microwave downstream plasma type reactor. Preferably, a one step process is needed for high throughput fabrication schemes.

### SUMMARY OF INVENTION

One objective of the present invention is to provide a high throughput plasma ashing method of removing a high dose implant photoresist layer that requires only one plasma etch step and does not include C_{M}F_{N} gases.

A further objective of the present invention is to provide a method of stripping a carbonized crust and a high dose implanted photoresist layer while minimizing damage to the substrate.

A still further objective of the present invention is to provide a stripping method for a high dose implant photoresist layer that is compatible with a reactor that has a RF discharge source and bias power and with a reactor that has a microwave downstream plasma.

Yet another objective of the present invention is to provide a stripping method for an organic material that is compatible with either an asher which does not apply a bias power or with an etcher that does use a bias power.

These objectives are accomplished in one embodiment by providing a substrate that is typically silicon but alternatively may be based on silicon-germanium, gallium-arsenide, or silicon-on-insulator technologies. Isolation regions such as shallow trench isolation (STI) structures filled with an insulator material are formed in the substrate by conventional means. A partially formed metal oxide semiconductor field effect transistor (MOSFET) is formed between adjacent isolation regions. The partially formed transistor is comprised of a gate electrode on a gate dielectric layer, sidewall spacers adjacent to the gate electrode and gate dielectric layer, and lightly doped source/drain (LDD) regions in the substrate. All the features of the MOSFET are fabricated by conventional methods up to this point.

In one embodiment, a p-type MOSFET hereafter called a PMOS transistor is to be fabricated adjacent to an n-type MOSFET hereafter referred to as an NMOS transistor. The active region comprising a substrate, gate electrode, gate dielectric layer, and sidewall spacers on the partially formed PMOS transistor are masked by a photoresist layer while an adjacent active region in a partially formed NMOS transistor is exposed by an opening in the same photoresist pattern. A high dose ion implant with n-type ions such as As or P is performed to dope the exposed portion of the NMOS transistor including substrate regions that will become source/drain regions in the substrate. Next, a key feature of the invention involves a plasma ash to remove the ion implanted photoresist layer that has a crust because of the ion implant.

A process chamber is provided in which a plasma may be generated with a RF discharge source and bias power or where the plasma may be a microwave downstream plasma. The substrate is held in place by a chuck and the chamber is evacuated with a vacuum. The substrate may then be heated while a flow of oxygen and one or more fluorocarbons C_{X}H_{Y}F_{Z} such as CHF₃, CH₂F₂, or CH₃F are flowed into the chamber. A plasma is struck by applying a RF power and the photoresist is removed by a plasma etch in one continuous step in preferably less than about 2 minutes. The fast but relatively soft etch minimizes polysilicon loss on the gate electrodes to less than 10 Angstroms and oxide loss on the gate dielectric layer to less than 4 Angstroms. The stripping method also reduces loss in silicon substrate regions that are exposed to the plasma. Optionally, an asher with a microwave plasma source may be utilized.

A second photoresist may be patterned to cover the partially formed NMOS transistor followed by a p-type ion implant with B or In ions into exposed regions of the PMOS transistor. The ion implanted photoresist is then removed by a similar process to the one just described for stripping the photoresist over the PMOS transistor. Conventional methods are employed to complete the PMOS and NMOS transistors. The reduced polysilicon loss improves ldsat and lower oxide loss reduces the contact junction leakage.

Other embodiments requiring a high dose ion implant process are possible during the semiconductor device fabrication. The plasma strip method of this invention minimizes thickness loss in all oxide, silicon, and polysilicon layers that are exposed to a plasma etchant during the removal of a photoresist implant mask. The layers might be in portions of the substrate that are exposed during the entire etch process or a layer may be below an implant mask and uncovered during the latter stages of the photoresist ashing step. Furthermore, the method of the present invention may be used to remove hardened photoresist or a photoresist crust caused by a reactive ion etch process. Other organic materials such as anti-reflective coatings (ARCs) may also be stripped by the method of this invention.

### BRIEF DESCRIPTION OF THE DRAWINGS

FIG. 1a is a cross-sectional view that depicts a high dose ion implant step into a photoresist mask that covers a partially formed transistor on a substrate.

FIG. 1b shows an upper carbonized crust, a middle ion implanted region, and a lower undoped region in the photoresist layer as a result of the implant in FIG. 1a.

FIG. 1c is a cross-sectional view showing a thickness loss in the polysilicon gate and in the substrate and an undercut in the gate dielectric layer after a prior art etch method to remove the ion implanted photoresist in FIG. 1b.

FIGS. 2-4 are cross-sectional views illustrating a process of performing a high dose ion implant into an NMOS transistor while an adjacent PMOS transistor is protected by a photoresist mask which is subsequently stripped according to one embodiment of the present invention.

FIGS. 5-7 are cross-sectional views illustrating a process of performing a high dose ion implant into a PMOS transistor while an adjacent NMOS transistor is protected by a photoresist mask which is subsequently stripped according to a second embodiment of the present invention.

### DETAILED DESCRIPTION OF THE INVENTION

The present invention is a method of improving the reliability and performance of NMOS and PMOS transistors, resistors, diodes, and other microelectronic devices that require a high dose implanted photoresist to be stripped during the course of a fabrication scheme. The invention is not limited to the specific examples described herein and the figures are not necessarily drawn to scale.

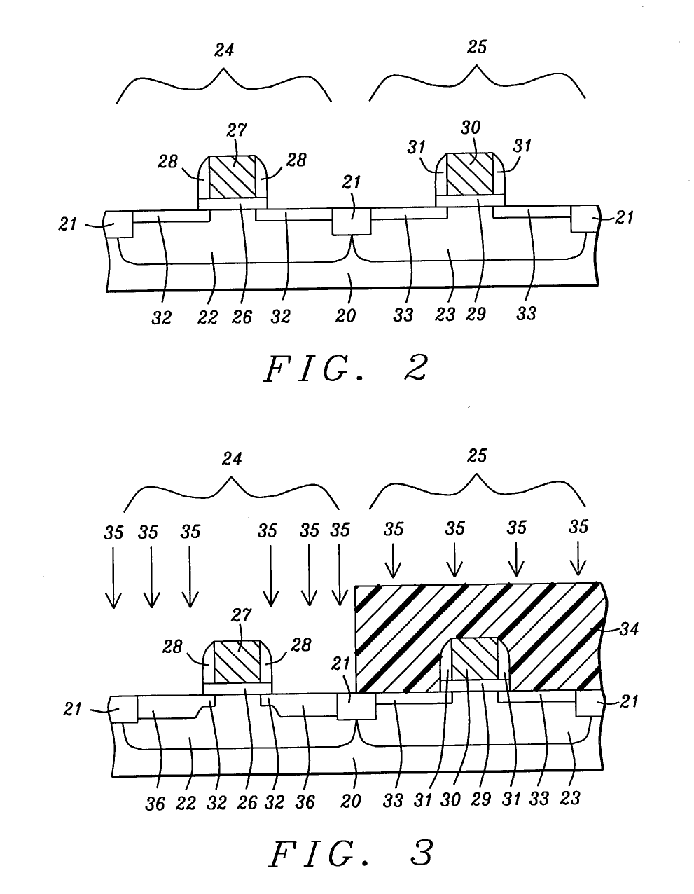

A first embodiment is illustrated in FIGS. 2-4 and is a method that is especially effective in stripping a photoresist masking layer that has been implanted with a high dose of p-type ions. However, the method of the present invention may also be used to remove hardened photoresist or a photoresist crust caused by a reactive ion etch process or other process conditions such as a elevated temperatures that thermally harden a photoresist layer. Furthermore, other organic materials such as an ARC layer below a photoresist layer can be stripped by the method of this invention.

In one aspect, the strip process is performed prior to a sequence involving an n-type ion implant and a subsequent photoresist strip as described in a second embodiment. Optionally, the p-type ion implant and photoresist strip sequence of the first embodiment may be performed following an n-type ion implant and photoresist strip sequence described in the second embodiment. Alternatively, stripping a photoresist implanted with p-type ions may be performed in a fabrication scheme without an n-type implant and n-type implanted photoresist strip sequence on a partially formed transistor on the same substrate.

Referring to FIG. 2, a substrate 20 is provided that is typically silicon but may be based on silicon-germanium, gallium-arsenide, or silicon-on-insulator technologies. The substrate 20 may have active and passive devices in a substructure (not shown). Substrate 20 also has shallow trench isolation (STI) features 21 that separate partially formed transistors 24, 25.

Partially formed PMOS transistor 24 includes an N+well 22, lightly doped source/drain regions 32 containing p-type ions, a gate dielectric layer 26, gate layer 27, and sidewall spacers 28. Note that while only one sidewall spacer 28 is depicted on each side of gate layer 27, this invention also applies to transistor structures where two sidewall spacers are on each side of a gate layer. In one embodiment, gate dielectric layer 26 which has a thickness of about 5 to 50 Angstroms is SiO₂ which is preferably deposited by a plasma enhanced chemical vapor deposition (PECVD) or CVD method. Optionally, a high temperature oxidation or rapid thermal oxidation technique can be used to form a SiO₂ dielectric layer 26.

In another embodiment, gate dielectric layer 26 may be comprised of a high k dielectric layer on an interfacial layer as appreciated by those skilled in the art. An interfacial layer typically consists of SiO₂, silicon oxynitride, or silicon nitride and is formed by a rapid thermal process, a low pressure CVD method or a PECVD technique. Examples of high k dielectric layers are Ta₂O₅, TiO₂, Al₂O₃, ZrO₂, HfO₂, Y₂O₃, La₂O₅ and their aluminates and silicates that are formed by various methods including metal organic CVD, atomic layer deposition, and CVD. A high k dielectric option for gate dielectric layer 26 enables an increase in the physical dielectric thickness to suppress tunneling current and thereby lower the gate leakage current in the transistor. Furthermore, a high temperature anneal may be performed to improve the performance of the high k dielectric layer by a method known to those skilled in the art.

Gate layer 27 is preferably doped or undoped polysilicon but may be amorphous silicon and has a thickness in the range of about 300 to 3000 Angstroms. Sidewall spacers 28, 31 are typically formed from silicon nitride or SiO₂.

Partially formed NMOS transistor 25 includes a P+ well 23, lightly doped source/drain regions 33 containing n-type ions, a gate dielectric layer 29, gate layer 30, and sidewall spacers 31. Note that while only one sidewall spacer 31 is depicted on each side of gate layer 30, this invention also applies to transistor structures where two sidewall spacers are on each side of a gate layer. Gate dielectric layer 29 which has a similar but not necessarily equal thickness to that of gate dielectric layer 26 is not limited to oxide but may also consist of a high k dielectric material on an interfacial layer as mentioned previously. Gate layer 30 is preferably doped or undoped polysilicon but may be amorphous silicon and has a similar but not necessarily equal thickness to that of gate layer 27.

Referring to FIG. 3, a photoresist that may be a positive tone or negative tone composition is coated to a thickness between about 5000 and 15000 Angstroms on substrate 20 and is patterned to form a photoresist layer 34 that covers partially formed NMOS transistor 25. Photoresist layer 34 is patterned by exposure through a patterned mask with one or more wavelengths in a range of about 10 to 600 nm. Optionally, the pattern in photoresist layer 34 is generated by an electron beam (e-beam) method such as a projection e-beam technique.

An ion implant 35 is then performed which delivers a high dose of p-type ions such as In or B ions in exposed regions of PMOS transistor 24. A typical implant 35 includes an energy of from 5 to 90 keV and a dose between about 10¹⁰ and 10¹⁷ ions/cm². Highly doped source/drain regions 36 are formed in substrate 20 between gate dielectric layer 26 and STI features 21. Sidewall spacers 28 and gate layer 27 also receive a high dose of ions. Partially formed NMOS transistor 25 is protected from the implant by photoresist layer 34.

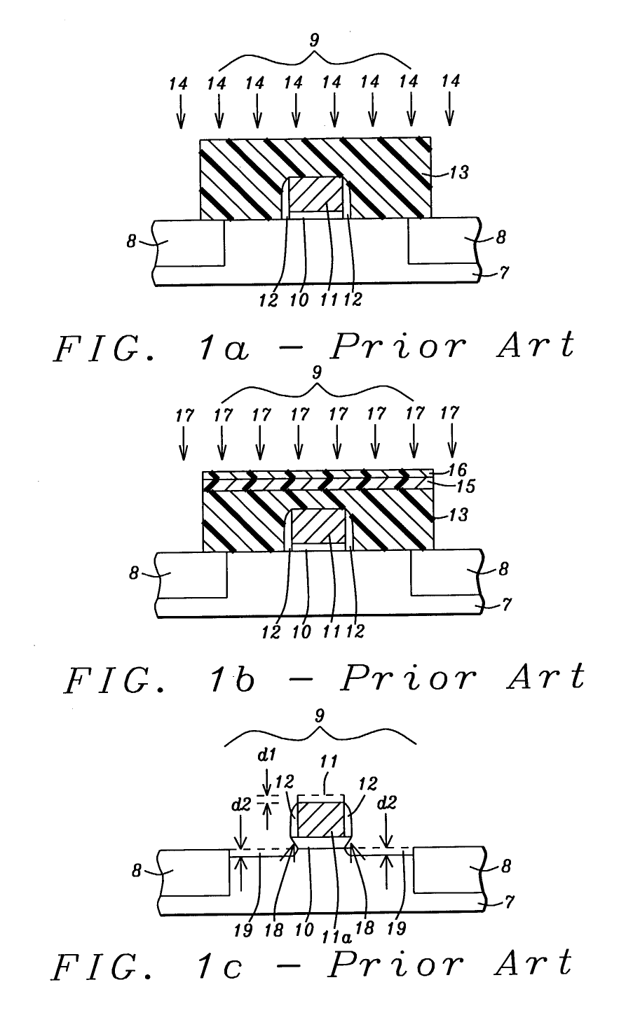

Referring to FIG. 4, photoresist layer 34 is transformed by the ion implant process 35 into a photoresist layer 34a with a carbonized crust. Although prior art methods teach or suggest that a plasma etch which includes oxygen and a C_{M}F_{N} fluorocarbon like CF₄ or C₂F₆ is preferred for removing a high dose implanted photoresist, the inventors have found that this combination leads to an unacceptable amount of substrate loss, gate layer damage, and oxide undercut as illustrated in FIG. 1c. Gate layer 27, gate dielectric layer 26, and substrate 20 in PMOS transistor 24 are especially susceptible to damage during a plasma ashing of photoresist 34a since PMOS transistor 24 is exposed to the etchant during the entire ashing step.

A key feature of the present invention will now be described. The inventors have discovered that a plasma treatment 37 which includes oxygen and one or more fluorocarbon gases C_{X}H_{Y}F_{Z} where x,y, and z are integers ≧1 such as CH₃F, CH₂F₂, and CHF₃ provides an advantage over prior art methods since thickness loss in the substrate, gate layer, and gate dielectric layer are significantly reduced. More preferably, y is greater than or equal to z in order to minimize damage to substrate and exposed oxide and polysilicon surfaces. Furthermore, the gas mixture used to generate the plasma may be additionally comprised of N₂ or N₂H₄. Optionally, the plasma treatment is performed without oxygen.

As an example of plasma treatment step 37, the substrate 20 with partially formed PMOS and NMOS transistors 24, 25 is fastened to a chuck in a process chamber that is part of an etch tool or an ashing tool and a vacuum is applied to remove all gases. The process chamber preferably has an inductively coupled plasma (ICP) or transformer coupled plasma (TCP) source. The plasma may be generated in an etch chamber from a RF discharge source and bias power or may be from a microwave downstream plasma flow as in an asher. However, other chamber architectures and plasma delivery systems are acceptable in this invention so far as they enable a photoresist removal rate of between 0.2 and 2 microns per minute and preferably at least 0.5 microns a minute to enable a sufficient throughput.

In one embodiment, the plasma is generated in the process chamber with the following conditions. The chamber is purged and then oxygen with a flow rate between 200 and 10000 standard cubic centimeters per minute (sccm) and one or more C_{X}H_{Y}F_{Z} gases such as CH₃F, CH₂F₂, and CHF₃ each with a flow rate of between 1 and 500 sccm are flowed into the process chamber while the substrate is heated to a temperature of from 20° C. to 300° C. The ratio of oxygen flow rate to C_{X}H_{Y}F_{Z} flow rate is preferably in the range of about 10:1 to 1000:1. The combined gas flow provides a pressure in the range of 10 mtorr to 5 torr in the process chamber. Once the desired temperature is reached, a plasma is struck by applying a RF power of from 200 to 2000 Watts. The plasma treatment is continued while the temperature is maintained in the 20° C. to 300° C. range for a predetermined amount of time or until photoresist layer 34a is removed as indicated by an end point detect method. At this point the substrate may be cleaned with a conventional wet cleaning method to remove any residues present on transistors 24, 25 and on substrate 20.

Other examples where the first embodiment may be applied such as stripping a thermally hardened photoresist all employ plasma treatment step 37 as described above for a predetermined amount of time or until an end point is indicated by an end point detect method. A wet clean step may follow step 37 to remove any residues.

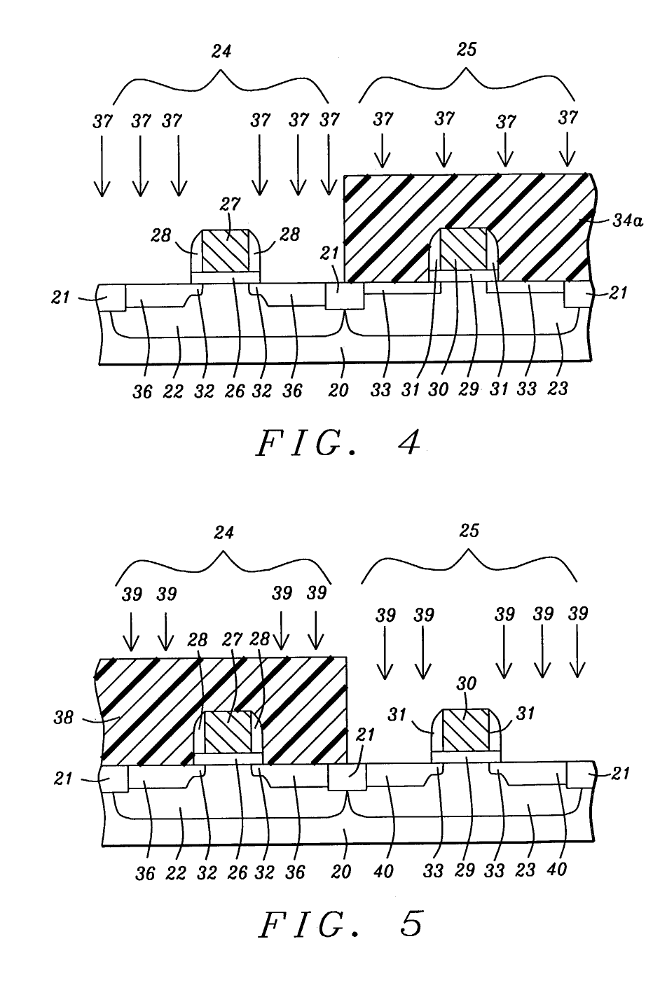

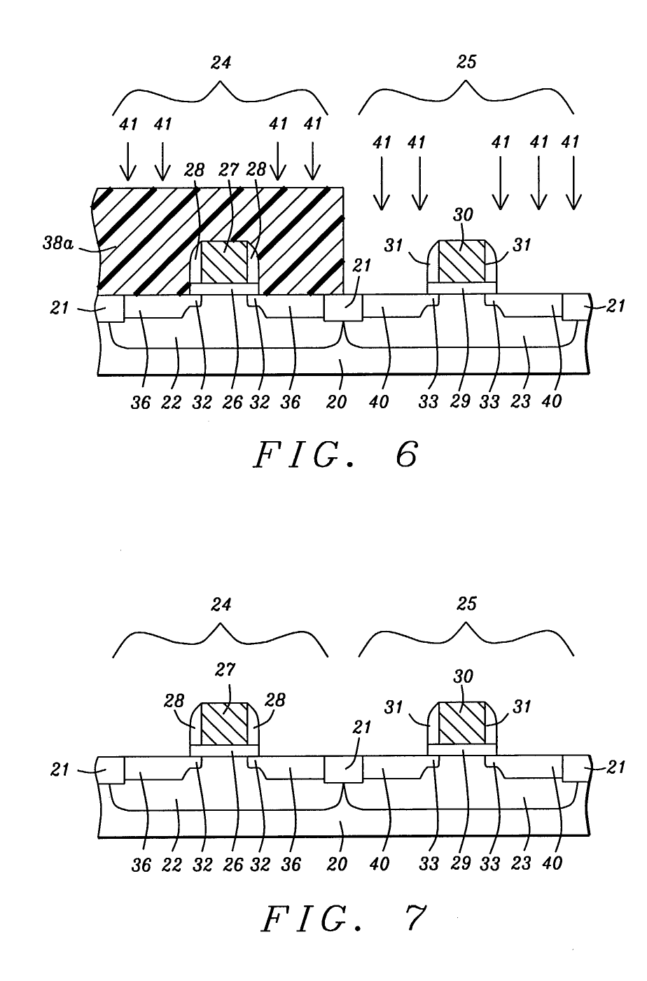

A second embodiment is illustrated in FIGS. 5-7 and is a method of stripping a photoresist masking layer that has been implanted with a high dose of n-type ions. However, the method of the present invention may also be used to remove hardened photoresist or a photoresist crust caused by a reactive ion etch process or other process conditions such as a elevated temperatures that thermally harden a photoresist layer. Other organic materials such as an ARC may be removed by this method.

In one aspect, the strip process is performed following a sequence involving a p-type ion implant and a photoresist strip as described in the first embodiment. Optionally, the n-type ion implant and photoresist strip sequence of the second embodiment may be performed prior to a p-type ion implant and photoresist strip sequence described in the first embodiment. Alternatively, stripping a photoresist implanted with n-type ions may be performed in a fabrication scheme without having a p-type implant and p-type implanted photoresist strip sequence on a partially formed transistor on the same substrate

Referring to FIG. 5, a substrate 20 is provided and has STI features 21, a partially formed PMOS transistor 24, and a partially formed NMOS transistor 25 as described in the first embodiment. A photoresist is coated to a thickness between about 5000 and 15000 Angstroms on substrate 20 and patterned to form a photoresist layer 38 that covers partially formed PMOS transistor 24. Photoresist layer 38 preferably has the same composition as photoresist layer 34 described in the first embodiment but may be any positive tone or negative tone photoresist material that is exposed through a patterned mask with one or more wavelengths in a range of about 10 to 600 nm. Optionally, the pattern in photoresist layer 38 is generated by an electron beam (e-beam) exposure such as a projection e-beam technique.

An ion implant 39 is then performed which delivers a high dose of n-type ions such as As or P ions in exposed regions of NMOS transistor 25. A typical implant 39 includes an energy of from 5 to 90 keV and a dose between about 10¹⁰ and 10¹⁷ ions/cm². Highly doped source/drain regions 40 are formed in substrate 20 between gate dielectric layer 29 and STI features 21. Sidewall spacers 31 and gate layer 30 also receive a high dose of ions. Partially formed PMOS transistor 24 is protected from the implant by photoresist layer 38.

Referring to FIG. 6, photoresist layer 38 is transformed by the ion implant process 39 into a photoresist layer 38a with a carbonized crust. Although prior art methods teach or suggest that a plasma etch which includes oxygen and a C_{M}F_{N} fluorocarbon like CF₄ or C₂F₆ is preferred for removing a high dose implanted photoresist, the inventors have found that this combination leads to an unacceptable amount of damage to substrate, gate layers, and to gate dielectric layers as depicted in FIG. 1c. Gate layer 30, gate dielectric layer 29, and substrate 20 in NMOS transistor 25 are especially susceptible to damage during a plasma ashing of photoresist 38a since NMOS transistor 25 is exposed to the etchant during the entire ashing step.

A key feature of this invention is that the inventors have discovered a plasma treatment 41 which includes oxygen and one or more C_{X}H_{Y}F_{Z} gases where x, y, and z are integers ≧1 such as CH₃F, CH₂F₂, and CHF₃ that is able to significantly reduce damage to PMOS transistor 24 and to substrate 20, gate layer 30 and gate dielectric layer 29 in NMOS transistor 25 during the removal of ion implanted photoresist layer 38a. More preferably, y is greater than or equal to z in order to minimize damage to substrate and exposed oxide and polysilicon surfaces. The gas mixture used to generate a plasma may be further comprised of N₂ or N₂H₄. Optionally, the plasma treatment is performed without oxygen.

In one embodiment, a plasma treatment 41 is performed according to the following sequence. The substrate 20 with partially formed PMOS and NMOS transistors 24, 25 is fastened to a chuck in a process chamber that is part of an etch tool or an ashing tool and a vacuum is applied to remove all gases. The process chamber preferably has an inductively coupled plasma (ICP) or transformer coupled plasma (TCP) source. The plasma may be generated in an etch chamber from a RF discharge source and bias power or may be from a microwave downstream plasma flow as in an asher. However, other process chamber architectures and plasma delivery systems are acceptable in this invention so far as they enable a photoresist removal rate of between 0.2 and 2 microns per minute and preferably at least 0.5 microns a minute.

The process leading up to and including the generation of a plasma to perform plasma treatment step 41 is the same as described previously in the first embodiment for plasma treatment step 37. The plasma treatment step 41 proceeds until photoresist layer 38a is removed after a predetermined amount of time or as indicated by an end point detect method. A wet clean step may be employed at this point to remove any residues on the surface of substrate 20 or on any part of transistors 24, 25.

Other process steps are then performed to complete the fabrication of transistors 24, 25. For instance, a resistor protective oxide layer or RPO (not shown) may be deposited on the substrate 20 by a chemical vapor deposition method followed by a thermal anneal to activate the source/drain regions 36, 40 formed by the ion implant steps 35, 39. Further process steps to complete transistors 24, 25 are known to those skilled in the art and are not described herein.

Other examples where the second embodiment may be applied such as stripping a thermally hardened photoresist or an ARC layer all employ plasma treatment step 41 as described above for a predetermined amount of time or until an end point is indicated by an end point detect method. A wet clean step may follow step 41 to remove residues.

One advantage of the present invention as provided by either the first or second embodiment is that a low polysilicon etch rate and thereby a low gate layer loss on a partially formed transistor is achieved. A process where polysilicon loss is minimized will result in an improved saturation current (Idsat) in the final device. For example, the inventors have practiced a prior art method that involves a plasma generated from C₂F₆ and O₂ in stripping a patterned photoresist layer having a high ion implant dose. The photoresist layer is formed on a partially formed transistor as depicted in the first and second embodiments. The plasma treatment conditions were optimized to minimize damage to the polysilicon gate. However, an average polysilicon thickness loss of 14 Angstroms is observed. When the process was repeated with CH₃F in place of C₂F₆, an average thickness loss of only 5.9 Angstroms was determined. The process was repeated again with CH₂F₂ in place of C₂F₆ and an average thickness loss of 7.6 Angstroms was observed.

These results show that a plasma treatment method for stripping an ion implanted photoresist that involves a C_{X}H_{Y}F_{Z} gas such as CH₃F or CH₂F₂ in combination with O₂ is preferred over a conventional method based on O₂ and C_{M}F_{N} gases since polysilicon loss is reduced by about 50% or more. A trend is observed in which the polysilicon loss is reduced by increasing the hydrogen content in the CₓH_{Y}F_{Z} gas. Therefore, CH₃F and CH₂F₂ are preferred over CHF₃ in the photoresist removal method of the present invention.

A second advantage of the present invention is a low oxide etch rate and thereby a low gate dielectric layer loss on a partially formed transistor is achieved. A process where oxide etch rate is minimized while removing a high dose ion implanted photoresist will result in an improved contact junction leakage. For example, the inventors have practiced a prior art method that involves a plasma generated from C₂F₆ and O₂ in stripping a patterned photoresist layer having a high ion implant dose. The photoresist layer is formed on a partially formed transistor having a SiO₂ gate dielectric layer as depicted in the first and second embodiments. An average oxide thickness loss of 30 Angstroms is observed with a conventional process. When the process was repeated according to the present invention with CH₃F in place of C₂F₆, an average thickness increase of 3.8 Angstroms was measured. These results show that a plasma treatment method for stripping an ion implanted photoresist that involves CH₃F in combination with O₂ is preferred over a conventional method based on O₂ and CMFN gases since there is a substantial reduction in oxide loss.

A similar reduction in silicon substrate thickness loss is realized when replacing a conventional photoresist strip process involving O₂ and C_{M}F_{N} gases by a method of the present invention.

While this invention has been particularly shown and described with reference to, the preferred embodiment thereof, it will be understood by those skilled in the art that various changes in form and details may be made without departing from the spirit and scope of this invention. For example, the advantages cited above are also realized when using the present invention to strip a photoresist that has been hardened by a RIE process or by a thermal treatment.

We claim:

1. A method for removing an organic layer from a substrate, comprising:
(a) providing a substrate having an organic layer thereon; and
(b) generating a plasma from a gas mixture that contacts said substrate and said organic layer wherein said gas mixture is comprised of one or more C_{X}H_{Y}F_{Z} gases where x,y, and z are integers >1.

2. The method of claim I wherein said organic layer is a photoresist layer.

3. The method of claim I wherein said plasma is generated with a RF discharge source and bias power or is a microwave downstream plasma.

4. The method of claim 2 wherein said photoresist layer is formed on a substrate having a gate layer on a gate dielectric layer, said gate layer and gate dielectric layer are part of a partially formed transistor.

5. The method of claim 1 wherein the gas mixture used to generate a plasma is further comprised of oxygen.

6. The method of claim 1 wherein the gas mixture used to generate a plasma is further comprised of one or more gases which are O₂, N₂, and N₂H₄.

7. The method of claim 2 wherein said photoresist layer is a patterned layer that has been implanted with B, In, As, or P ions with a concentration in doped regions of at least 10¹⁰ ions/cm³.

8. The method of claim 1 further comprised of heating said substrate to a temperature in a range of about 20° C. to 300° C. during the plasma treatment.

9. The method of claim 1 wherein the C_{X}H_{Y}F_{Z} gas is CH₃F, CH₂F₂, or CHF₃.

10. The method of claim 1 wherein the C_{X}H_{Y}F_{Z} gas is CH₃F.

11. The method of claim 1 wherein the composition of the C_{X}H_{Y}F_{Z} gas is such that y is greater than or equal to z.

12. The method of claim 5 wherein said plasma is generated with a RF power of about 200 to 2000 Watts, a chamber pressure from about 10 mtorr to 5 torr, a C_{X}H_{Y}F_{Z} gas flow rate of about 1 to 500 standard cubic centimeters per minute (sccm), and an oxygen flow rate of about 200 to 10000 sccm

13. The method of claim 5 wherein the ratio of the O₂ flow rate to the C_{X}H_{Y}F_{Z} gas flow rate is from about 10:1 to 1000:1.

14. The method of claim 1 wherein an end point detect method is used to determine when to stop the plasma treatment.

15. The method of claim 1 wherein the chamber used for the plasma treatment has an inductively coupled plasma (ICP) or transformer coupled plasma (TCP) source.

16. The method of claim 1 wherein the process chamber is part of an etching tool or is in an ashing tool.

17. A method for removing an ion implanted patterned photoresist layer on a substrate, comprising:
(a) providing a substrate having a patterned photoresist layer formed thereon, said photoresist layer has been implanted with a dose of ions;
(b) placing said substrate in a process chamber;
(c) heating the substrate and flowing a gas mixture into said chamber wherein said gas mixture is comprised of oxygen and one or more C_{X}H_{Y}F_{Z} gases where x,y, and z are integers ≧1;
(d) generating a plasma that contacts said substrate and said photoresist; and
(e) continuing said plasma treatment until said photoresist is essentially removed.

18. The method of claim 17 wherein said substrate is comprised of one or more partially formed transistors each having a gate dielectric layer, a gate layer on said gate dielectric layer, and one or more sidewall spacers on each side of said gate layer.

19. The method of claim 18 wherein said gate layer is polysilicon and said gate dielectric layer is SiO₂.

20. The method of claim 18 wherein the gate dielectric layer is comprised of a high k dielectric layer on an interfacial layer.

21. The method of claim 17 wherein said substrate is silicon.

22. The method of claim 17 wherein said photoresist layer has an upper region that is doped with B, In, As, or P ions.

23. The method of claim 22 wherein the doped region of said photoresist layer has a dopant concentration in the range of about 10¹⁰ to 10¹⁷ ions/cm³.

24. The method of claim 17 wherein said substrate is heated to a temperature in a range of about 20° C. to 300° C. that is maintained during the plasma treatment.

25. The method of claim 17 wherein the C_{X}H_{Y}F_{Z} gas is CH₃F, CH₂F₂, or CHF₃.

26. The method of claim 17 wherein the C_{X}H_{Y}F_{Z} gas is CH₃F.

27. The method of claim 17 wherein the composition of the C_{X}H_{Y}F_{Z} gas is such that y is greater than or equal to z.

28. The method of claim 17 wherein said plasma is generated with a RF power of about 200 to 2000 Watts, a chamber pressure from about 10 mtorr to 5 torr, a C_{X}H_{Y}F_{Z} gas flow rate of about 1 to 500 sccm, and an oxygen flow rate of about 200 to 10000 sccm.

29. The method of claim 17 wherein the ratio of the oxygen flow rate to the C_{X}H_{Y}F_{Z} gas flow rate is from about 10:1 to 100:1.

30. The method of claim 17 wherein said plasma is generated from a gas mixture that is further comprised of N₂ or N₂H₄.

31. The method of claim 17 wherein an end point detect method is used to determine when to stop the plasma treatment.

32. The method of claim 17 wherein the plasma is generated with a RF discharge source and bias power or is a microwave downstream plasma.

33. The method of claim 17 wherein said plasma treatment is performed in a process chamber that is part of an etching tool or is in an ashing tool.

34. The method of claim 17 wherein said photoresist was implanted with ions during a process to form highly doped source/drain regions in a PMOS or NMOS transistor.

35. The method of claim 17 wherein the sequence (a) to (e) is performed at least twice on a substrate during the fabrication of a device, a first sequence (a) to (e) to remove a p-type ion implanted photoresist over one or more PMOS transistors and a second sequence (a) to (e) to remove an n-type ion implanted photoresist over one or more NMOS transistors.

36. The method of claim 17 further comprised of a wet clean step after the plasma treatment step to remove any residues from the substrate.
